(19) United States
(12) Patent Application Publication
(10) Pub. No.: US 2013/0069105 A1
(43) Pub. Date: Mar. 21, 2013

(54) METHOD FOR ENCAPSULATION OF ORGANIC ELECTRONIC DEVICES

(71) Applicant: Yijian Shi, Mountain View, CA (US)

(72) Inventor: Yijian Shi, Mountain View, CA (US)

(21) Appl. No.: 13/510,604

(22) PCT Filed: Sep. 21, 2010
(86) PCT No.: PCT/US10/49711

§ 371 Date: May 17, 2012

Related U.S. Application Data
(60) Provisional application No. 61/245,787, filed on Sep. 25, 2009.

(51) Int. Cl. H01L 33/54; H01L 33/48

(52) U.S. Cl. 257/100; 438/26; 257/E33.059; 257/E33.056

(57) ABSTRACT

The disclosure provides methods and materials for efficiently encapsulating electronic devices such as organic electroluminescent devices. The disclosure also provides electronic devices prepared by such methods. In one embodiment, for example, there is provided a method for preparing an electroluminescent device comprising forming a groove in a substrate and/or forming a groove in an encapsulation layer, depositing a desiccant in the groove or grooves, and bonding the substrate to the encapsulation layer.

### CROSS REFERENCE TO RELATED APPLICATIONS

This application claims priority under 35 U.S.C. §119 to U.S. Provisional Application Ser. No. 61/245,787, filed Sep. 25, 2009, the contents of which is incorporated herein by reference in its entirety.

### TECHNICAL FIELD

The present invention is directed to methods for enhancing the performance of organic light emitting devices and other organic electrical devices by reducing device susceptibility to ambient elements such as oxygen and moisture. The invention is further directed to the devices produced by such methods. The invention finds utility, for example, in the field of electronic devices.

### BACKGROUND

In certain embodiments of traditional organic light emitting diodes (OLEDs), the OLED comprises a plurality of component layers in a sandwich-type structure (often referred to as an OLED “stack”). The OLED stack is typically supported on a substrate such as glass. Such layers include one or more organic materials such as an organic emissive material, an organic dielectric material, etc. Because these and other materials used in the construction of OLEDs may be sensitive to certain elements present in ambient conditions (e.g, oxygen, water, etc.), it is common to encapsulate the OLED stack using materials that are impervious to such elements. The commonly adopted approach for OLED encapsulation uses a cover glass (or a metal cover) to protect the OLED stack from coming in contact with ambient oxygen and moisture. The cover glass and the OLED substrate glass create a “device chamber” within which the OLED stack sits, and are held together using an organic sealant located around the perimeter of the OLED stack. The organic sealant is typically an UV curable epoxy material. In this configuration, the sealant along the perimeter of the device is the weakest area of the encapsulation, both mechanically and chemically.

Organic sealants are generally porous, and allow permeation of small molecules, such as oxygen and water, through the sealant layer. For this reason, a desiccant is generally required to remove any moisture that permeates into the device chamber. Typically, the desiccant is located within the device chamber so as to provide maximum surface area of desiccant material. For example, the desiccant may be coated on the inside surface of the cover glass, facing the OLED stack. U.S. Pat. No. 6,803,127 describes such an embodiment. Such devices require a transparent desiccant in order to be top emitting devices (i.e., devices that emit light from the side of the top electrode); devices employing non-transparent desiccants are limited to bottom emitting configurations (i.e., configurations that emit light through the substrate). Furthermore, oxygen and moisture that enters the device chamber are able to react with either the desiccant or the OLED stack, thereby decreasing the effectiveness of the desiccant layer.

There remains a need in the art to overcome the abovementioned drawbacks, as well as generally to develop new methods and materials for manufacturing efficient and low cost organic electrical devices (OEDs) that are stable to ambient conditions for long periods of time. Ideal methods would utilize materials that are readily available or easily prepared, provide significant enhancements in device stability over long periods of time, minimize the number of process steps, and/or provide highly reproducible results.

### SUMMARY OF THE INVENTION

The present invention is directed to addressing one or more of the above-mentioned drawbacks, and in particular in providing methods and materials for effectively encapsulating electronic devices (such as, for example, electroluminescent devices (ELDs)) and protecting them against degradation from environmental elements.

In one aspect of the invention, there is provided an electronic device comprising: a plurality of device layers arranged in a component stack, wherein the component stack comprises a top face, a bottom face, and peripheral edges; and an encapsulation surrounding the component stack and comprising a first substrate, a second substrate, a sealant, and a desiccant. The sealant forms a bond between the first and second substrates. The desiccant is positioned within the encapsulation and surrounds the peripheral edges of the component stack.

In another aspect of the invention, there is provided an electronic device comprising: a first substrate comprising a device side and an external side, wherein the device side comprises a device area and further comprises a first sealing area surrounding the device area; a second substrate comprising a second sealing area; an electronic device stack disposed on the first substrate in the device area; an optional spacer configured to make contact with the first substrate in the first sealing area and with the second substrate in the second sealing area; a sealant contacting the first sealing area and the second sealing area, wherein the sealant bonds the second substrate to the first substrate; a first groove in either the first substrate, the second substrate, or the optional spacer; and a desiccant disposed within the groove.

In another aspect of the invention, there is provided an encapsulation layer for an electronic device comprising a bonding area suitable for contacting a substrate and a groove suitable for receiving a liquid or solid desiccant.

In another aspect of the invention, there is provided a substrate for an electronic device comprising a face suitable for supporting the layers of an electronic device, wherein the face comprises a device area and a sealing area surrounding the device area, wherein the sealing area comprises a groove for receiving a liquid or solid desiccant.

In another aspect of the invention, there is provided a method for encapsulating an electronic device, the method comprising: providing a first substrate, a second substrate, and an optional spacer; forming a groove in the first substrate, the second substrate, the optional spacer, or any combination thereof; depositing a desiccant in the groove; and bonding the first substrate to the second substrate using a sealant.

In some embodiments, the invention comprises any of the above devices or methods, wherein one or both of the first and second substrates comprise a rim.

In some embodiments, the invention comprises any of the above devices or methods, wherein the first substrate comprises a rim, and the first sealing area is partially or completely disposed on a surface of the rim, or wherein the second substrate comprises a rim, and the second sealing area is partially or completely disposed on a surface of the rim.

In some embodiments, the invention comprises any of the above devices or methods, wherein the first substrate comprises a rim and the second substrate comprises a rim, and wherein the first sealing area is partially or completely disposed on the rim of the first substrate and the second sealing area is partially or completely disposed on the rim of the second substrate.

In some embodiments, the invention comprises any of the above devices or methods, wherein the first groove is present in the first substrate, and wherein the second substrate optionally comprises a second groove, or wherein the first groove is present in the second substrate, and wherein the first substrate optionally comprises a second groove.

In some embodiments, the invention comprises any of the above devices or methods, wherein the optional spacer is present, and wherein the electronic device comprises a second groove in either the first substrate, the second substrate, or the spacer.

In some embodiments, the invention comprises any of the above devices or methods, wherein the second groove is present, and wherein the first and second grooves are positioned such that their centers are substantially aligned.

In some embodiments, the invention comprises any of the above devices or methods, wherein the desiccant partially or completely fills the groove.

In some embodiments, the invention comprises any of the above devices or methods, wherein the electronic device stack comprises a bottom electrode contacting the first substrate, an electroluminescent layer, and a top electrode, and wherein the electronic device is configured to emit photons through the first substrate, through the second substrate, or through both the first and second substrates.

In some embodiments, the invention comprises any of the above devices or methods, wherein the periphery of the encapsulation layer comprises an elevated rim, and wherein the bonding area is disposed on a surface of the elevated rim.

In some embodiments, the invention comprises any of the above devices or methods, wherein the groove is disposed on the surface of the elevated rim.

In some embodiments, the invention comprises any of the above devices or methods, wherein the periphery of the device side further comprises an elevated rim, and wherein the sealing area and groove are disposed on a surface of the elevated rim.

In some embodiments, the invention comprises any of the above devices or methods, wherein the groove is formed around the periphery of the first substrate, the periphery of the second substrate, or the periphery of both the first and second substrates.

In some embodiments, the invention comprises any of the above devices or methods, wherein the first substrate is provided having the component layers of an electronic device disposed thereon.

In some embodiments, the invention comprises any of the above devices or methods, wherein the method comprises forming a groove in the first substrate, and wherein the component layers of an electronic device are deposited on the first substrate after the groove is formed in the first substrate.

In some embodiments, the invention comprises any of the above devices or methods, wherein the method comprises forming a groove in the second substrate but not the first substrate.

In some embodiments, the invention comprises any of the above devices or methods, wherein the first substrate has an elevated rim, or wherein the second substrate has an elevated rim, or wherein the first substrate and the second substrate both have elevated rims.

Other aspects of the invention will be apparent from the description that follows, including the claims and examples.

### BRIEF DESCRIPTION OF THE DRAWINGS

FIGS. 1a-1d provide plane (top) views of substrates and electronic devices according to the invention.

FIGS. 2a-2f provide side views of devices according to the invention. In the devices shown in the figures, grooves are present in the top or bottom substrate, or both top and bottom substrates. An optional spacer element is not present.

FIGS. 3a and 3b provide side views of devices according to the invention. In the devices shown in the figures, an optional spacer element is present. Grooves are present in the spacer or in the top and bottom substrate.

FIGS. 4a and 4b provide side views of devices according to the invention. In the devices shown in the figures, desiccant is disposed directly on the bonding region of the substrate (FIG. 4a) or encapsulation layer (FIG. 4b).

FIG. 5 provides a side view of a device according to the invention. In the device shown, sealant is present in the device cavity.

### DETAILED DESCRIPTION OF THE DISCLOSURE

It is to be understood that the terminology used herein is for the purpose of describing particular embodiments only, and is not intended to be limiting. The definitions provided herein are not meant to be mutually exclusive. For example, it will be appreciated that some chemical moieties may be encompassed by more than one definition.

The term “alkyl” as used herein refers to a branched or unbranched saturated hydrocarbon group typically although not necessarily containing 1 to about 24 carbon atoms, such as methyl, ethyl, n-propyl, isopropyl, n-butyl, isobutyl, t-butyl, octyl, decyl, and the like, as well as cycloalkyl groups such as cyclopentyl, cyclohexyl and the like. Generally, although again not necessarily, alkyl groups herein may contain 1 to about 18 carbon atoms, and such groups may contain 1 to about 12 carbon atoms. The term “lower alkyl” intends an alkyl group of 1 to 6 carbon atoms. “Substituted alkyl” refers to alkyl substituted with one or more substituent groups, and the terms “heteroatom-containing alkyl” and “heteroalkyl” refer to an alkyl substituent in which at least one carbon atom is replaced with a heteroatom, as described in further detail infra. If not otherwise indicated, the terms “alkyl” and “lower alkyl” include linear, branched, cyclic, unsubstituted, substituted, and/or heteroatom-containing alkyl or lower alkyl, respectively.

The term “alkenyl” as used herein refers to a linear, branched or cyclic hydrocarbon group of 2 to about 24 carbon atoms containing at least one double bond, such as ethenyl, n-propenyl, isopropenyl, n-butenyl, isobutenyl, octenyl, decenyl, tetradecenyl, hexadecenyl, eicosenyl, tetracosenyl, and the like. Generally, although again not necessarily, alkenyl groups herein may contain 2 to about 18 carbon atoms, and for example may contain 2 to 12 carbon atoms. The term “lower alkenyl” intends an alkenyl group of 2 to 6 carbon atoms. The term “substituted alkenyl” refers to alkenyl substituted with one or more substituent groups, and the terms “heteroatom-containing alkenyl” and “heteroalkenyl” refer to alkenyl in which at least one carbon atom is replaced with a heteroatom. If not otherwise indicated, the terms “alkenyl” and “lower alkenyl” include linear, branched, cyclic, unsubstituted, substituted, and/or heteroatom-containing alkenyl and lower alkenyl, respectively.

The term “alkynyl” as used herein refers to a linear or branched hydrocarbon group of 2 to 24 carbon atoms containing at least one triple bond, such as ethynyl, n-propynyl, and the like. Generally, although again not necessarily, alkynyl groups herein may contain 2 to about 18 carbon atoms, and such groups may further contain 2 to 12 carbon atoms. The term “lower alkynyl” intends an alkynyl group of 2 to 6 carbon atoms. The term “substituted alkynyl” refers to alkynyl substituted with one or more substituent groups, and the terms “heteroatom-containing alkynyl” and “heteroalkynyl” refer to alkynyl in which at least one carbon atom is replaced with a heteroatom. If not otherwise indicated, the terms “alkynyl” and “lower alkynyl” include linear, branched, unsubstituted, substituted, and/or heteroatom-containing alkynyl and lower alkynyl, respectively.

If not otherwise indicated, the term “unsaturated alkyl” includes alkenyl and alkynyl, as well as combinations thereof.

The term “alkoxy” as used herein intends an alkyl group bound through a single, terminal ether linkage; that is, an “alkoxy” group may be represented as —O-alkyl where alkyl is as defined above. A “lower alkoxy” group intends an alkoxy group containing 1 to 6 carbon atoms, and includes, for example, methoxy, ethoxy, n-propoxy, isopropoxy, t-butyloxy, etc. Substituents identified as “C₁-C₆ alkoxy” or “lower alkoxy” herein may, for example, may contain 1 to 3 carbon atoms, and as a further example, such substituents may contain 1 or 2 carbon atoms (i.e., methoxy and ethoxy).

The term “aryl” as used herein, and unless otherwise specified, refers to an aromatic substituent generally, although not necessarily, containing 5 to 30 carbon atoms and containing a single aromatic ring or multiple aromatic rings (such as 1 to 3 rings) that are fused together, directly linked, or indirectly linked (such that the different aromatic rings are bound to a common group such as a methylene or ethylene moiety). Aryl groups may, for example, contain 5 to 20 carbon atoms, and as a further example, aryl groups may contain 5 to 12 carbon atoms. For example, aryl groups may contain one aromatic ring or two fused or linked aromatic rings, e.g., phenyl, naphthyl, biphenyl, diphenylether, diphenylamine, benzophenone, and the like. “Substituted aryl” refers to an aryl moiety substituted with one or more substituent groups, and the terms “heteroatom-containing aryl” and “heteroaryl” refer to an aryl substituent, in which at least one carbon atom is replaced with a heteroatom, as will be described in further detail infra. If not otherwise indicated, the term “aryl” includes unsubstituted, substituted, and/or heteroatom-containing aryl substituents.

The term “aralkyl” refers to an alkyl group with an aryl substituent, and the term “alkaryl” refers to an aryl group with an alkyl substituent, wherein “alkyl” and “aryl” are as defined above. In general, aralkyl and alkaryl groups herein contain 6 to 30 carbon atoms. Aralkyl and alkaryl groups may, for example, contain 6 to 20 carbon atoms, and as a further example, such groups may contain 6 to 12 carbon atoms.

The term “olefinic group” intends a mono-unsaturated or di-unsaturated hydrocarbon group of 2 to 12 carbon atoms. Preferred olefinic groups within this class are sometimes herein designated as “lower olefinic groups,” intending a hydrocarbon moiety of 2 to 6 carbon atoms containing a single terminal double bond. The latter moieties may also be termed “lower alkenyl.”

The term “alkylene” as used herein refers to a difunctional saturated branched or unbranched hydrocarbon chain containing from 1 to 24 carbon atoms. “Lower alkylene” refers to alkylene linkages containing from 1 to 6 carbon atoms, and includes, for example, methylene (—CH₂—), ethylene (—CH₂CH₂—), propylene (—CH₂CH₂CH₂—), 2-methylpropylene (—CH₂—CH(CH₃)—CH₂—), hexylene (—(CH₂)₆—) and the like.

The term “amino” is used herein to refer to the group —NZ¹Z² wherein Z¹ and Z² are hydrogen or nonhydrogen substituents, with nonhydrogen substituents including, for example, alkyl, aryl, alkenyl, aralkyl, and substituted and/or heteroatom-containing variants thereof.

The term “heteroatom-containing” as in a “heteroatom-containing alkyl group” (also termed a “heteroalkyl” group) or a “heteroatom-containing aryl group” (also termed a “heteroaryl” group) refers to a molecule, linkage or substituent in which one or more carbon atoms are replaced with an atom other than carbon, e.g., nitrogen, oxygen, sulfur, phosphorus or silicon, typically nitrogen, oxygen or sulfur. Similarly, the term “heteroalkyl” refers to an alkyl substituent that is heteroatom-containing, the term “heterocyclic” refers to a cyclic substituent that is heteroatom-containing, the terms “heteroaryl” and heteroaromatic” respectively refer to “aryl” and “aromatic” substituents that are heteroatom-containing, and the like. Examples of heteroalkyl groups include alkoxyaryl, alkylsulfanyl-substituted alkyl, N-alkylated amino alkyl, and the like. Examples of heteroaryl substituents include pyrrolyl, pyrrolidinyl, pyridinyl, quinolinyl, indolyl, furyl, pyrimidinyl, imidazolyl, 1,2,4-triazolyl, tetrazolyl, etc., and examples of heteroatom-containing alicyclic groups are pyrrolidino, morpholino, piperazino, piperidino, tetrahydrofuranyl, etc.

“Hydrocarbyl” refers to univalent hydrocarbyl radicals containing 1 to about 30 carbon atoms, including 1 to about 24 carbon atoms, further including 1 to about 18 carbon atoms, and further including about 1 to 12 carbon atoms, including linear, branched, cyclic, saturated and unsaturated species, such as alkyl groups, alkenyl groups, aryl groups, and the like. “Substituted hydrocarbyl” refers to hydrocarbyl substituted with one or more substituent groups, and the term “heteroatom-containing hydrocarbyl” refers to hydrocarbyl in which at least one carbon atom is replaced with a heteroatom. Unless otherwise indicated, the term “hydrocarbyl” is to be interpreted as including unsubstituted, substituted, heteroatom-containing, and substituted heteroatom-containing hydrocarbyl moieties.

“Halo” or “halogen” refers to fluoro, chloro, bromo or iodo, and usually relates to halo substitution for a hydrogen atom in an organic compound. Of the halos, chloro and fluoro are generally preferred.

By “substituted” as in “substituted hydrocarbyl,” “substituted alkyl,” “substituted aryl,” and the like, as alluded to in some of the aforementioned definitions, is meant that in the hydrocarbyl, alkyl, aryl, or other moiety, at least one hydrogen atom bound to a carbon (or other) atom is replaced with one or more non-hydrogen substituents. Examples of such substituents include, without limitation: functional groups such as halo, hydroxyl, sulfhydryl, C₁-C₂₄ alkoxy, C₂-C₂₄ alkenyloxy, C₂-C₂₄ alkynyloxy, C₅-C₂₀ aryloxy, acyl (including C₂-C₂₄ alkylcarbonyl (—CO-alkyl) and C₆-C₂₀ arylcarbonyl (—CO-aryl)), acyloxy (—O-acyl), C₂-C₂₄ alkoxycarbonyl (—(CO)—O-alkyl), C₆-C₂₀ aryloxycarbonyl (—(CO)—O-aryl), halocarbonyl (—CO)—X where X is halo), C₂-C₂₄ alkylcarbonato (—O—(CO)—O-alkyl), C₆-C₂₀ arylcarbonato (—O—(CO—O-aryl), carboxy (—COOH), carboxylato (—COO⁻), carbamoyl (—(CO)—NH₂), mono-substituted C₁-C₂₄ alkylcarbamoyl (—(CO)—NH(C₁-C₂₄ alkyl)), di-substituted alkylcarbamoyl (—(CO)—N(C₁-C₂₄ alkyl)₂), mono-substituted arylcarbamoyl (—(CO)—NH-aryl), thiocarbamoyl (—(CS)—NH₂), carbamido (—NH—(CO)—NH₂), cyano (—C≡N), isocyano (—N⁺≡C⁻), cyanato (—O—C≡N), isocyanato (—O—⁺≡C⁻), isothiocyanato (—S—C≡N), azido formyl (—(CO)—H), thioformyl (—(CS)—H), amino (—NH₂), mono- and di-(C₁-C₂₄ alkyl)-substituted amino, mono- and di-(C₅-C₂₀ aryl)-substituted amino, C₂-C₂₄ alkylamido (—NH—(CO)-alkyl), C₅-C₂₀ arylamido (—NH—(CO)-aryl), imino (—CR═NH where R=hydrogen, C₁-C₂₄ alkyl, C₅-C₂₀ aryl, C₆-C₂₀ alkaryl, C₆-C₂₀ aralkyl, etc.), alkylimino (—CR═N(alkyl), where R=hydrogen, alkyl, aryl, alkaryl, etc.), arylimino (—CR═N(aryl), where R=hydrogen, alkyl, aryl, alkaryl, etc.), nitro (—NO₂), nitroso (—NO), sulfo (—SO₂—OH), sulfonato (—SO₂—O⁻), C₁-C₂₄ alkylsulfanyl (—S-alkyl; also termed “alkylthio”), arylsulfanyl (—S-aryl; also termed “arylthio”), C₁-C₂₄ alkylsulfinyl (—(SO)-alkyl), C₅-C₂₀ arylsulfinyl (—(SO)-aryl), C₁-C₂₄ alkylsulfonyl (—SO₂-alkyl), C₅-C₂₀ arylsulfonyl (—SO₂-aryl), phosphono (—P(O)(OH)₂), phosphonato (—P(O)(O⁻)₂), phosphinato (—P(O)(O⁻)), phospho (—PO₂), and phosphino (—PH₂), mono- and di-(C₁-C₂₄ alkyl)-substituted phosphino, mono- and di-(C₅-C₂₀ aryl)-substituted phosphino; and the hydrocarbyl moieties C₁-C₂₄ alkyl (including C₁-C₁₈ alkyl, further including C₁-C₁₂ alkyl, and further including C₁-C₆ alkyl), C₂-C₂₄ alkenyl (including C₂-C₁₈ alkenyl, further including C₂-C₁₂ alkenyl, and further including C₂-C₆ alkenyl), C₂-C₂₄ alkynyl (including C₂-C₁₈ alkynyl, further including C₂-C₁₂ alkynyl, and further including C₂-C₆ alkynyl), C₅-C₃₀ aryl (including C₅-C₂₀ aryl, and further including C₅-C₁₂ aryl), and C₆-C₃₀ aralkyl (including C₆-C₂₀ aralkyl, and further including C₆-C₁₂ aralkyl). In addition, the aforementioned functional groups may, if a particular group permits, be further substituted with one or more additional functional groups or with one or more hydrocarbyl moieties such as those specifically enumerated above. Analogously, the above-mentioned hydrocarbyl moieties may be further substituted with one or more functional groups or additional hydrocarbyl moieties such as those specifically enumerated.

When the term “substituted” appears prior to a list of possible substituted groups, it is intended that the term apply to every member of that group. For example, the phrase “substituted alkyl and aryl” is to be interpreted as “substituted alkyl and substituted aryl.”

Unless otherwise specified, reference to an atom is meant to include isotopes of that atom. For example, reference to H is meant to include ¹H, ²H (i.e., D) and ³H (i.e., T), and reference to C is meant to include ¹²C and all isotopes of carbon (such as ¹³C).

As used herein, the term “transparent” refers to a material that is permeable to electromagnetic radiation. In the specific context of a transparent material employed in an LED, the term refers to a material that is permeable to the wavelengths of electromagnetic radiation that are emitted by the LED. Unless stated otherwise, the term includes materials that are completely permeable as well as materials that are semi-permeable.

The devices of the invention are, generally, electronic devices that comprise a plurality of layers, also referred to herein as a “component stack,” “device stack,” or simply “stack.” The component stack is supported on a substrate. The substrate may or may not be considered as one of the layers of the component stack. For the purposes of this disclosure, however, the substrate is referred to as the “bottom” layer of the devices of the invention. Thus, a first layer is “above” a second layer if the first layer is further from the substrate than the second layer—i.e., the second layer is between the substrate and the first layer. Similarly, a first layer is “below” a second layer if the first layer is closer to the substrate than the second layer—i.e., the first layer is between the substrate and the second layer. The terms “above” and “below” as used herein are determined on an axis that is perpendicular to the substrate. This convention of nomenclature is not intended to necessarily imply any particular overall order of deposition of the layers. Thus, although the substrate is referred to as the “bottom” layer, and all other layers are “above” the substrate, such references are not meant to imply that the substrate must necessarily be provided first, and that all layers are deposited onto the substrate. Embodiments wherein the layers of a device are deposited one after another, beginning with the substrate, are within the scope of the invention. Embodiments wherein the layers of the device are deposited one after another, ending with the substrate, are also within the scope of the invention.

Throughout this disclosure, references are made to “top” and “bottom” surfaces of layers. Generally, the “top” surface of a layer refers to the surface that is furthest away from the substrate, and the “bottom” surface of a layer refers to the surface that is closest to the substrate. It will be appreciated that the top and bottom surfaces are determined on an axis that is perpendicular to the substrate.

In some embodiments, then, the invention provides materials and methods for encapsulating electronic devices. The electronic devices are typically layered devices, wherein the component layers are supported on a substrate.

The encapsulation comprises at least the following components: the substrate (also referred to herein as a “first substrate”); an encapsulating layer (also referred to herein as a “second substrate”); a desiccant; and a bonding material (also referred to herein as a “sealant”) that bonds the substrate to the encapsulating layer. The encapsulation also comprises a spacer component (e.g., either a rim that is an integral part of the substrate, encapsulating layer, or both, or an independent spacer element) that separates the substrate from the encapsulating layer. The encapsulation completely encloses an electronic device within a “device cavity,” and forms a bather that protects the devices from environmental elements. For example, the encapsulation protects the devices from moisture (i.e., water), air (particularly the oxygen component of air), atmospheric pollutants, and other substances that could be harmful to the device components.

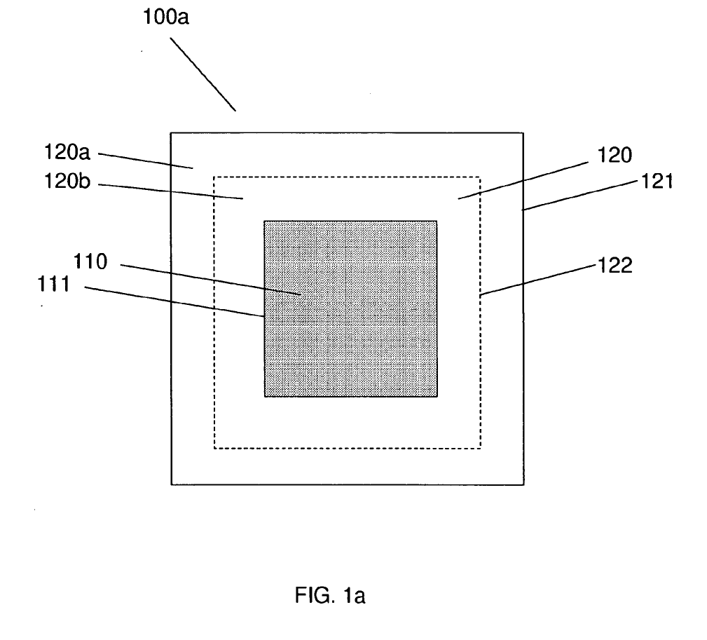

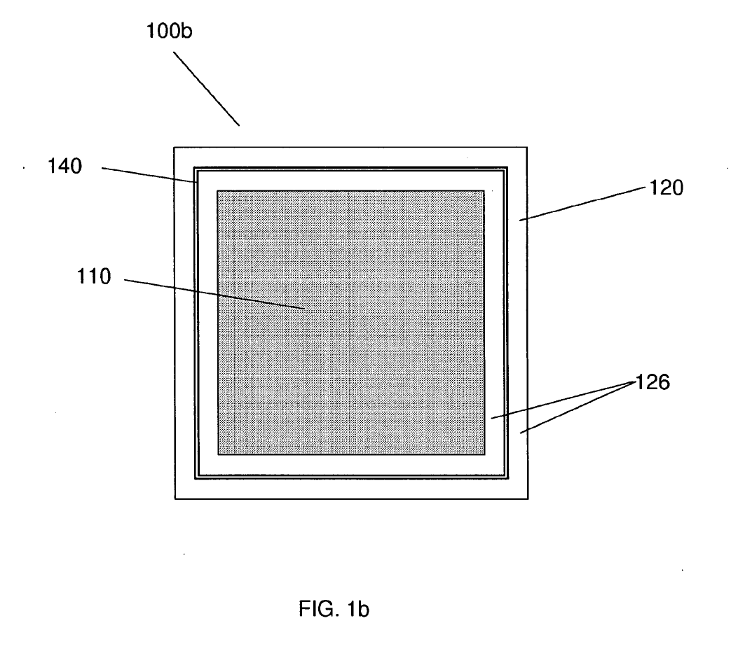

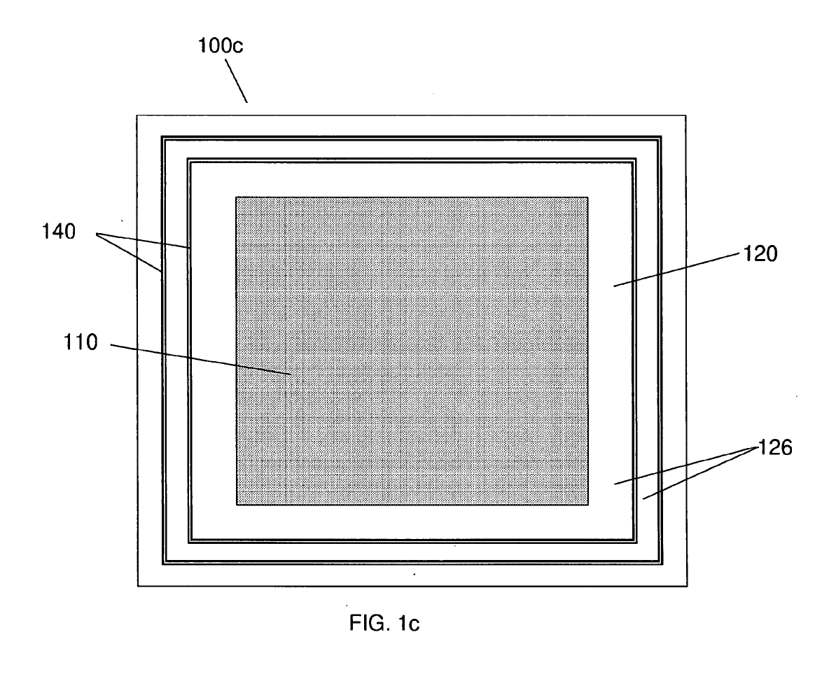

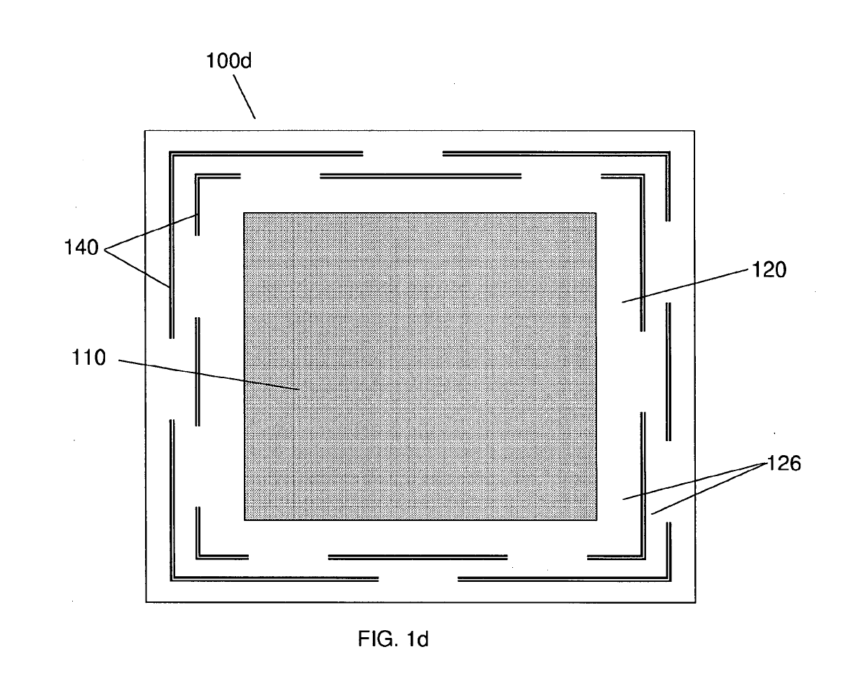

The encapsulation comprises the substrate (also referred to herein as a “first substrate”) upon which the device components are disposed. The substrate may be smooth and flat, or may be patterned. The top surface of the substrate (i.e., the surface that supports the device stack) comprises a device region and a bonding region (also referred to herein as a “first bonding region”) that surrounds the device region. The substrate may comprise a recessed region that allows the device stack to be partially or completely recessed below the top face of the substrate. The recessed region may correspond in dimensions to the device region or may be larger than the device region. The substrate may comprise a rim and/or a groove, both of which are described in more detail below. The component layers are generally smaller in area than the substrate such that the substrate extends beyond the component layers. FIG. 1, discussed below, shows an example top view of the substrate and device stack illustrating these concepts. The substrate may be prepared from any suitable material, examples of which are also provided below. In some embodiments, the substrate has a thickness ranging from about 100 μm to about 10 mm or greater, or from about 200 μm to about 8 mm, or from about 300 μm to about 6 mm, or from about 400 μm to about 5 mm, or from about 500 μm to about 5 mm, or from about 500 μm to about 4 mm, or from about 500 μm to about 3 mm, or from about 500 μm to about 2 mm, or from about 500 μm to about 1 mm. In some embodiments, the substrate has a thickness that is less than about 10 mm, or less than about 8 mm, or less than about 6 mm, or less than about 5 mm, or less than about 4 mm, or less than about 3 mm, or less than about 2 mm, or less than about 1 mm, or less than about 0.5 mm. In some embodiments, the substrate has a thickness that is greater than about 0.5 mm, or greater than about 1 mm, or greater than about 2 mm, or greater than about 3 mm, or greater than about 4 mm, or greater than about 5 mm, or greater than about 6 mm, or greater than about 8 mm, or greater than about 10 mm.

The encapsulation comprises an encapsulation layer (also referred to herein as a “second substrate”), which is bonded to the substrate. The encapsulation layer may be smooth and flat, or may be patterned. The encapsulation layer may comprise a rim and/or a groove, both of which are described in more detail below. The encapsulation layer comprises an encapsulation bonding region (also referred to herein as a “second bonding region”) which is the region of the encapsulation layer that makes contact with the substrate (via the sealant, as described herein). Typically, the encapsulation layer does not contact any components of the device stack, although in some embodiments the encapsulation layer may contact the uppermost layer of the device stack. The encapsulation layer may be prepared from any suitable material, examples of which are also provided below. In some embodiments, the encapsulation layer has a thickness ranging from about 100 μm to about 5 mm or greater, or from about 200 μm to about 4 mm, or from about 300 μm to about 3 mm, or from about 400 μm to about 2 mm, or from about 500 μm to about 1 mm. In some embodiments, the encapsulation layer has a thickness that is less than about 5 mm, or less than about 4 mm, or less than about 3 mm, or less than about 2 mm, or less than about 1 mm, or less than about 0.5 mm. In some embodiments, the encapsulation layer has a thickness that is greater than about 0.5 mm, or greater than about 1 mm, or greater than about 2 mm, or greater than about 3 mm, or greater than about 4 mm, or greater than about 5 mm. In some embodiments, the substrate and the encapsulation layer are the same thickness, and in other embodiments, they are different thicknesses.

In some embodiments, the substrate comprises a rim (referred to herein as a “substrate rim”). The rim functions to separate the encapsulation layer from the device region of the substrate. In some embodiments, the encapsulation layer comprises a rim (referred to herein as an “encapsulation layer rim”). In some embodiments, the substrate and the encapsulation layer each comprise a rim. As used herein the term “rim” refers to a raised portion of a layer that is an integral part of the layer and is located around the periphery of the layer. The depth of the rim (or the combined depth of the two rims, wherein encapsulation layer rim and substrate rim are both present) is one factor that determines the amount of space that is between the encapsulation layer and the device region of the substrate. The rim(s) may have any depth suitable for the particular device, provided that the depth of the rim(s) is sufficient given the thickness of the device to be encapsulated (taking into consideration any recessing of the device into the substrate, etc.). The rim(s) may also be any width suitable for the particular device, provided that the width of the rim(s) is sufficient to accommodate the groove containing desiccant.

In some embodiments, the encapsulation comprises a spacer (also referred to herein as a “spacer element”). The spacer interfaces with both the first and second substrates, and, via the bonding material, forms a seal with both substrates. In preferred embodiments, the spacer contacts the bonding areas of the first and second substrates. Thus, the spacer comprises two spacer bonding areas, and each spacer bonding area contacts the bonding area of either the first or second substrate. The spacer element functions similarly to the rims of the substrate and/or encapsulation layer, but is a separate component (i.e., not integral with either the substrate or the encapsulation layer). That is, the spacer provides for space between the device area of the first substrate and the second substrate (space in which the device stack may be disposed). The spacer unit may be used with encapsulation components (i.e., first and second substrates) that have rims as well as with components that do not have rims.

For encapsulations of the invention that use a spacer, the spacer may be a single unit or may comprise a plurality of discreet subunits. Any combination of stacking spacer subunits (i.e., “thin” spacer subunits that form horizontal interfaces with each other and stack to form a thicker spacer) and slotting spacer subunits (i.e., “thick” spacer subunits that have vertical interfaces between subunits) may be used as appropriate.

Generally, the thickness of the spacer unit will be sufficient to ensure that the encapsulation as a whole is able to accommodate the encapsulated device stack. For example, where no rims are present in the first and second substrates, the spacer unit will have a thickness that is at least as great as the thickness of the device stack, and may be significantly greater than the thickness of the device stack. Where rims are present on the first, second, or both substrates, the thickness of the spacer may be less than the thickness of the device stack, or may be equal to or greater than such thickness. Where a spacer comprises multiple subunits that stack upon each other, the total thickness of the spacer will be determined by the thickness of each spacer subunit and the number of subunits. For example, for an encapsulation that requires a spacer having thickness “x,” the spacer may comprise “y” subunits each with a thickness of “x/y” (or wherein the average thickness is “x/y”).

The encapsulation further comprises one or more grooves. In embodiments, the groove(s) is/are suitable for receiving and containing a desiccant, further details about which are provided below. In some embodiments, a groove is disposed on the bonding region of the first substrate. In some embodiments, a groove is disposed on the bonding region of the second substrate. In some embodiments, grooves are disposed on the bonding regions of the first and second substrate. In embodiments that have grooves on both bonding regions of the first and second substrate, the grooves may align when the first and second substrates are bonded in position to form an encapsulation, or the grooves may be offset when the substrates are bonded together.

In some embodiments, the grooves are shaped in cross section as rectangular indentations into the substrate(s) (or, alternatively or in addition, into the spacer). Alternatively, the grooves may be other shapes, including triangular, U-shaped (i.e., straight side walls and a curved bottom), and irregular.

The depth of the grooves will vary depending on a number of factors such as the thickness of the substrate and other dimensions of the encapsulation. In some embodiments, the depth of the grooves will be between about 0.01 mm and 10 mm, or between about 0.1 mm and 5 mm, or between about 0.1 mm and 1 mm. In some embodiments, the depth of the grooves will be greater than 0.01 mm, or greater than 0.1 mm, or greater than 1 mm, or greater than 5 mm. In some embodiments, the depth of the grooves will be less than 5 mm, or less than 1 mm, or less than 0.1 mm, or less than 0.01 mm. In some embodiments, the depth of the grooves will be 0.1%, or 1%, or 5%, or 10%, or 25% of the thickness of the substrate in which it is disposed.

Multiple grooves may be present in a substrate according to the invention. For example, in some embodiments, the encapsulation comprises a bottom substrate having a plurality of grooves. The plurality of grooves may be concentric, such as shown in FIG. 1c (described below). In some embodiments, grooves may be discontinuous and/or staggered as shown in FIG. 1d (described below).

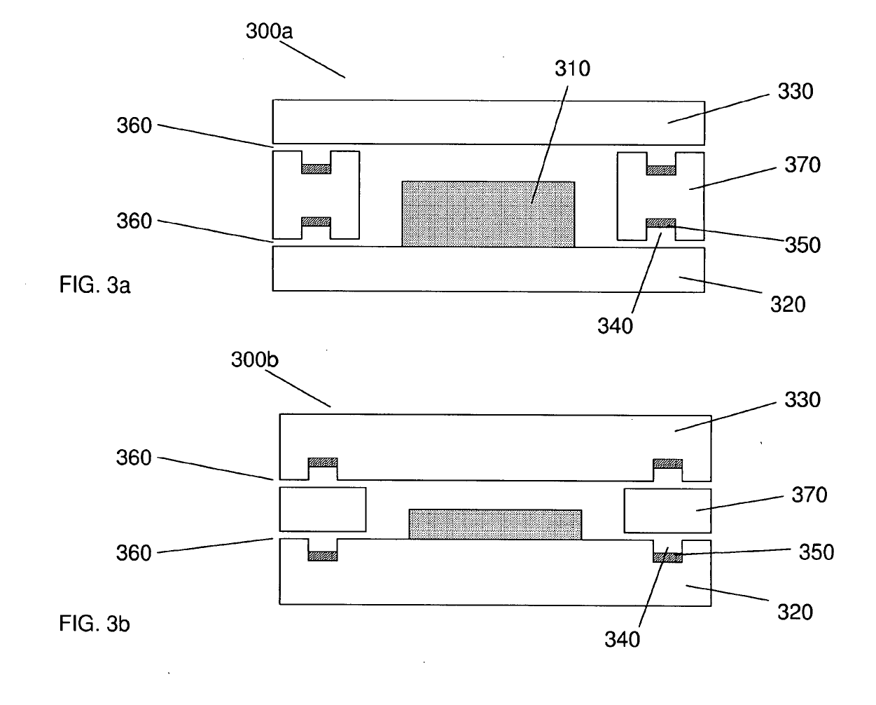

In embodiments that employ a spacer, the spacer may comprise one or more grooves. The spacer (whether comprised of one single unit, or of multiple subunits that stack on top of, or next to, one another) will generally have two spacer bonding areas, as described above. A groove may be disposed on either or both spacer bonding area. For example, FIG. 3a (described in more detail below) is an example embodiment in which a spacer (370) has two spacer bonding areas, and each spacer bonding area comprises a groove (340). The grooves in the embodiment shown in FIG. 3a are integrated into the spacer element. As an alternative (not shown in the Figures), the grooves in a spacer element may be present due to the configuration of a plurality of spacer subunits (i.e., stacking and slotting subunits are arranged so as to form a groove).

The encapsulation further comprises a desiccant. In some embodiments, the desiccant is disposed within the one or more grooves present in the encapsulation. In some embodiments, the desiccant completely fills the groove(s). In some embodiment, the desiccant partially fills the groove(s). In some embodiments, the desiccant is not disposed in the groove(s) during some portion of the manufacture of the device. For example, the desiccant may be disposed on the (grooveless) bonding area of the substrate or encapsulation layer prior to joining the substrate with the encapsulation layer. In such an embodiment, the desiccant may extend into the groove upon such joining.

The desiccant is employed in the encapsulations of the invention because it is common that the encapsulations may be slightly permeable to one or more of the abovementioned environmental elements. Typically, for example, the bonding material forms a seal that is semi-permeable, allowing a small percentage of moisture and oxygen to pass into the device cavity. The degree of permeability depends, of course, on the bonding material, and examples of suitable bonding materials are provided herein below. To protect the device components, the desiccant is present and situated in the encapsulation of the invention such that any moisture and/or oxygen that passes through the bonding material from the environment is first exposed to the desiccant prior to reaching the device components. Furthermore, the desiccant is situated such that it does not substantially interfere with any light emitted or received by the encapsulated device (e.g., when the device is a light emitting diode or photovoltaic device). Thus, where the encapsulated device comprises an OLED stack or a photovoltaic stack, the desiccant is located around and/or beyond the periphery of the stack rather than above the stack (i.e., rather than on an axis that is perpendicular to the substrate and passes through one or more components of the stack).

The encapsulation of the invention further comprises a sealant that forms a bond between components of the encapsulation. For example, the sealant forms a bond between the encapsulation layer and the substrate. Typically, there exists a transition region where the encapsulation bonding region and the substrate bonding region meet, and the sealant is disposed in such transition region. Thus, in embodiments, the sealant forms a bond between the encapsulation bonding region and the substrate bonding region.

The encapsulation forms a device cavity that completely surrounds the encapsulated device. In some embodiments, the device cavity is bigger than the encapsulated device (e.g., thicker and/or wider) such that there exists space between the layers of the device and one or more components of the encapsulation. In preferred such embodiments, the encapsulation layer does not contact any of the component layers of the encapsulated device (other than the substrate, as in some embodiments the substrate may be considered one of the device component layers), such that there is a space therebetween. The space may be evacuated (i.e., a vacuum) or may be filled with an inert element (such as an inert gas) prior to sealing the encapsulation. In some embodiments, the device cavity may be filled partially or completely with the sealant. In such embodiments, the sealant is preferably a transparent material if the encapsulated device is electroluminescent or photovoltaic and the sealant covers the path taken by photons entering or exiting the device. Also in such embodiments, it will be appreciated that the sealant contacts the first and second substrate in the bonding region as well as the device region.

In devices having a substance (e.g., an inert gas, or the sealant) filing excess space in the device cavity, the devices may be manufactured in any appropriate manner suitable to introduce the substance into the device cavity. For example, where an inert gas fills the device cavity, the devices may be manufactured in an inert gas environment. Also for example, where the sealant fills the excess space in the device cavity, the sealant may he applied over the entire device stack or on the encapsulation layer before joining the encapsulation layer with the substrate. For example, in one embodiment, a device stack is prepared on a substrate, and a portion of sealant is placed on the device stack and/or on the bonding region of the substrate. The encapsulation layer is then placed over the substrate and device stack, which compresses the sealant to partially or completely fill the device cavity. Subsequent curing of the sealant (e.g., using UV radiation) provides a permanent bond between the substrate and encapsulation layer.

### Devices and Materials

The encapsulation materials and methods of the invention are suitable for encapsulating a variety of electronic devices. For example, the devices may be organic electronic devices. Particularly suitable examples include organic light emitting diodes (OLEDs), organic capacitors, organic electricity generation devices (e.g., photovoltaic cells), organic transistors, etc. Such devices typically comprise a plurality of layers. For example, OLEDs comprise two electrode layers and an electroluminescent layer. Additional layers and components may be present, including dielectric layers, conducting layers, and optical layers such as lens layers. Combinations of similar layers are present for other electronic devices. It will be appreciated that, although OLED devices are referred to throughout much of this specification, such references are not meant to be limiting. Unless otherwise indicated or apparent from the context, the disclosure pertaining to OLEDs is equally applicable to other electronic devices.

Examples of devices suitable for the invention include, for example, those disclosed in U.S. Pat. No. 6,593,687 and co-pending PCT application number PCT/US2008/001025, the contents of which (pertaining to devices and device architecture) are incorporated herein by reference.

A variety of materials are suitable for preparing encapsulation according to the invention, examples of which are provided below. In addition, below is described material suitable for the preparation of devices suitable to be encapsulated by the encapsulation of the invention. Although OLEDs are used as an exemplary device, such disclosure should not be considered limiting, and materials for preparing other electronic devices (e.g., transistors, etc.) encapsulated according to the invention will be readily discernable by reference to the relevant literature.

In some embodiments, the devices of the invention are electroluminescent devices. Exemplary electroluminescent devices are organic light emitting diodes (OLEDs) that employ a substrate, two electrode layers, and an electroluminescent layer between the electrode layers. Additional layers and features may be incorporated as described herein. One of the electrode layers functions as an electron injection layer, and the other electrode layer functions as a hole injection layer (also referred to as an electron hole injection layer). Photons are generated within the electroluminescent layer by the recombination of electrons with electron holes. The photons are emitted by the device into the environment through the substrate and/or through one of the electrodes.

Where photon emission is through the substrate, the substrate is a transparent material. Furthermore, in order to reach the substrate, photons generated in the electroluminescent layer must pass through the bottom electrode. Such devices employ a patterned or transparent bottom electrode.

Generally, OLEDs comprise a first electrode, which may alternatively be referred to herein as the “bottom” electrode. In some embodiments, the first electrode functions as a cathode and/or electron injection electrode. In other embodiments, the first electrode functions as an anode and/or hole injection electrode. Examples of materials suitable for the first electrode are described below.

Above (and contacting) the bottom electrode is generally an electroluminescent layer. The electroluminescent layer may be made from any suitable electroluminescent material, and some such materials are described below. In preferred embodiments, the electroluminescent layer is conformally deposited over the bottom electrode.

Above (and contacting) the electroluminescent layer generally is an electrode layer. The electrode layer above the electroluminescent layer is referred to herein as the “second” electrode layer or the “top” electrode. The second electrode layer is, in some embodiments, a homogeneous layer that is conformally deposited over the electroluminescent layer. In some embodiments, the second electrode functions as a cathode and/or electron injection electrode. In other embodiments, the second electrode functions as an anode and/or hole injection electrode. Examples of materials suitable for the second electrode are described below. Where photon emission is through the top electrode, the top electrode will be prepared from a transparent material or will be patterned (i.e., the top electrode is not homogeneous).

The second electrode may be patterned (i.e., non-homogeneous) or un-patterned (i.e., homogeneous). For example, the second electrode may be patterned as desired using a shadow mask or other means for creating a patterned layer. Similarly, the electroluminescent layer may be patterned or un-patterned.

The devices of the invention comprise a substrate, and in some embodiments they may comprise a transparent or semi-transparent substrate. Transparent or semi-transparent materials that are suitable for substrates in the methods of the invention are compatible with the electronic devices disposed thereupon. Polymers and amorphous or semi-crystalline ceramics are preferred materials. Examples of inorganic materials include silicon dioxide (i.e., silica glass), various silicon-based glasses such as soda-lime glass and borosilicate glass, aluminum oxide, zirconium oxide, sodium chloride, diamond, and/or the like. Examples of transparent or semi-transparent polymeric materials include polyethylenenaphthalate, polycarbonate, polyethylene, polypropylene, polyester, polyimide, polyamides, polyacrylates, polymethacryates, and copolymers and mixtures thereof. The substrate may be rigid or flexible and may be of any suitable shape and configuration. A preferred substrate material is glass (i.e., silicon dioxide).

In some embodiments, the devices of the invention comprise a non-transparent material. Such materials are typically metals and/or non-transparent metal oxides. Suitable materials include, for example, Al, Ti, Co, Ni, Cu, Zn, Au, Ag, Sn, Mo, Zr, Pt, etc., as well as oxides thereof.

Typically, the encapsulation layer is prepared from a non-conductive, transparent or semi-transparent material. The material may be organic or inorganic. Materials suitable for the encapsulation layer include all those transparent, semi-transparent, and non-transparent materials described above as suitable for the substrate. In some embodiments, the encapsulation layer is silica glass (i.e., silicon dioxide).

It will be appreciated that, where the encapsulated device is meant to emit or absorb radiation (e.g., in an OLED or a photovoltaic cell), at least one of the substrate and the encapsulation layer will be transparent or semi-transparent. In some embodiments, both the substrate and the encapsulation layer will be transparent or semi-transparent.

Desiccants suitable for the devices of the invention include: alumina (i.e., aluminum oxide); clay (including bentonite clay, montmorillonite clay, etc.); alkali metals and alkaline earth metals (including potassium, magnesium, sodium, etc.); alkali metal oxides and alkaline earth metal oxides, alkali metal salts and alkaline earth metal salts (including carbonate salts; chloride salts, chlorate salts, perchlorate salts; sulfate salts, etc.); calcium salts (including calcium chloride, calcium sulfate (DRIERITE®), etc.); calcium hydride; cobalt chloride; copper sulfate; lithium chloride; lithium hydride, lithium bromide; magnesium salts (including magnesium sulfate, magnesium perchlorate, etc.); molecular sieves; phosphorus pentoxide; potassium carbonate; silica; sodium salts (including sodium chlorate, sodium sulfate, etc.); sodium hydroxide; sodium-benzophenone; sulfuric acid; etc.

Electrodes may be made from any appropriate material, and may be either transparent or non-transparent as appropriate for the specific device and application. In some embodiments, the devices of the invention comprise a top electrode layer (i.e., a second electrode) and a bottom electrode (i.e., a first electrode).

Materials such as metals, conductive metal oxides, and conjugated organic compounds are suitable as electrodes. Doped semiconductors and transparent materials are also suitable electrode materials. Example electrode materials include aluminum, titanium, copper, tungsten, silver, silicon, Indium Tin Oxide (ITO), Indium Zinc Oxide (IZO), pentacene, oligothiophenes and polythiophenes such as Poly(3,4-ethylenedioxythiophene) (PEDOT), carbon nanotubes, and the like. Further examples of materials that are suitable for these electrode layers in the methods of the invention are metals such as Au, Pt, Cr, Mn, Fe, Co, Ni, Zn, etc. Conducting metal oxides, such as oxides of Sn, In, La, Ti, Cr, Mn, Fe, Co, Ni, Cu, or Zn may also be used. Any other suitable conducting material (such as conducting polymers, carbon nanotubes, graphene, hybrids thereof, etc.) may also be used. In some embodiments, the device is an electroluminescent device, and the second electrode is made from a transparent material (such as ITO or the like). Such embodiments comprise devices that are able to emit photons from both sides of the device.

In any of the embodiments described herein, it will be appreciated that the electrodes can be deposited either as a single layer or as a combination of layers. For example, an electrode can be deposited as a pair of layers comprising anode and hole injection materials, or as a single layer. Similarly, an electrode can be deposited as a pair of layers comprising cathode and electron injection materials, or as a single layer. Furthermore, additional layers such as an encapsulation layer may be deposited over the second electrode.

In some embodiments, the devices encapsulated according to the invention further comprise a dielectric layer. For example, dielectric layers are present in certain OLED configurations as well as capacitors, etc. When prepared according to conventional methods, dielectric layers may be any suitable material capable of serving as a non-conductive barrier (e.g., between the electrodes to provide an electrical barrier and to prevent electrical shorting between the electrode layers). Materials include, for example, inorganic materials including oxides, nitrides, carbides, borides, silicides, or organic materials such as polyimide, polyvinylidene fluoride, parylene, as well as various sol-gel materials and pre-ceramic polymers. In certain embodiments, the dielectric layer is substantially pinhole free and composed from a high-resistivity material having an electrical resistivity no less than about 10⁸ ohm-cm, preferably no less than about 10¹² ohm-cm. Additional specific examples of suitable high-resistivity materials include, but are not limited to, silicon nitride, boron nitride, aluminum nitride, silicon oxide, titanium oxide, aluminum oxide.

In some embodiments, the devices encapsulated according to the invention further comprise a conductive layer. For example, a conductive layer may be used in devices where it is desirable to achieve a more homogeneous distribution of charges flowing through the electroluminescent layer.

The conductive material may be organic or inorganic (including metals and metal oxides). In preferred embodiments, the conductive material is organic. A preferred material for the conductive material is a transparent conductive polymer such as poly(3,4-ethylenedioxythiophene) (PEDOT). Derivatives and copolymers of PEDOT, such as PEDOT/polystyrenesulfonate, are further examples of suitable materials. Additional materials that are suitable include polyaniline (PANI), graphene, carbon nanotubes, and graphene-carbon nanotube hybrids. Non-polymeric organic materials that are conductive and transparent may also be used.

The conductive material may alternatively be a transparent inorganic material such as a transparent conducting oxide (TCO). Examples include conductive or semiconductive metals and/or metal oxide layers such as: tin oxide; zinc oxide; Ag; SnO₂:X, where X═Sb, Cl, or F; In₂O₃:X where X═Sb, Sn, Zn (i.e., indium tin oxide, indium zinc oxide, etc.); CdSnO₄; TiN; ZnO:X, where X═In, Al, B, Ga, F; Zn₂SnO₄; ZnSnO₃; and Cd₂SnO₄. Furthermore, the conductive material may be an ultra thin metal (e.g., Ag, Au, Cr, Al, Ti, Co, Ni, etc.). The conductive material may be any combinations of the metals, metal oxides, and organic conductive materials described herein.

The devices of the invention may further comprise an electroluminescent layer. Materials that are suitable for electroluminescent layers in the methods of the invention are materials capable of receiving a hole from the hole-injection layer and an electron from the electron-injection layer and emitting electromagnetic radiation (e.g., light) when the injected holes and electrons combine. Accordingly, in certain embodiments, the electroluminescent material may include any of a number of organic or inorganic compounds or mixtures thereof, such as multi-layers of organics or small molecules or the like. For instance, the electroluminescent layer may include a polymeric material or be composed of one or more small molecule materials. However, the material must contain at least one electroluminescent compound, for instance, an organic, inorganic or small molecule electroluminescent compound. In certain embodiments, the electroluminescent compound may include a simple organic molecule or complex polymer or copolymer. For example, a simple organic luminescent molecule may include tris(8-hydroxyquinolinato)-aluminum or perylene.

In certain embodiments, the electroluminescent material includes a polymer or copolymer. The molecular structure of a suitable polymer or copolymer may include a carbon-based or silicon-based backbone. The polymers and copolymers may be linear, branched, crosslinked or any combinations thereof, and may have a wide range of molecular weights from as low as about 5000 to more than 1,000,000. In the case of copolymers, the copolymers may be alternating, block, random, graft copolymers, or combinations thereof. Examples of suitable electroluminescent polymers useful in conjunction with the present invention include, but are not limited to, conjugated polymers such as, polyparaphenylenes, polythiophenes, polyphenylenevinylenes, polythienylvinylenes, polyfluorenes, 1,3,4-oxadiazole-containing polymers, and various derivatives and copolymers thereof.

An exemplary electroluminescent polymer is an arylamine-substituted poly(arylene-vinylene) polymer that has the general structure of formula (II) below:

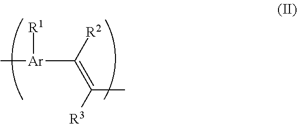

wherein: Ar is arylene, heteroarylene, substituted arylene or substituted heteroarylene containing one to three aromatic rings;

R¹ is the arylamine substituent and is of the formula —Ar¹—N(R⁴R⁵) wherein Ar¹ is as defined for Ar and R⁴ and R⁵ are independently hydrocarbyl, substituted hydrocarbyl, heteroatom-containing hydrocarbyl, or substituted heteroatom-containing hydrocarbyl; and

R² and R³ are independently selected from the group consisting of hydrido, halo, cyano, hydrocarbyl, substituted hydrocarbyl, heteroatom-containing hydrocarbyl, and substituted heteroatom-containing hydrocarbyl, or R² and R³ may together form a triple bond.

Other moieties may be as follows:

Ar may be a five-membered or six-membered arylene, heteroarylene, substituted arylene or substituted heteroarylene group, or may contain one to three such groups, either fused or linked. Preferably, Ar is comprised of one or two aromatic rings, and is most preferably comprised of a single aromatic ring that is five-membered or six-membered arylene, heteroarylene, substituted arylene or substituted heteroarylene. Ar¹, the arylene linking moiety in the arylamine substituent, is defined in the same way.

The substituents R² and R³ are generally hydrido but may also be halo (particularly chloro or fluoro) or cyano, or substituted or unsubstituted alkyl, alkoxy, alkenyl, alkynyl, aryl and heteroaryl.

R⁴ and R⁵ may the same or different and, as noted, are hydrocarbyl, substituted hydrocarbyl, heteroatom-containing hydrocarbyl, or substituted heteroatom-containing hydrocarbyl. For example, R⁴ and R⁵ may be alkyl, alkoxy-substituted alkyl, polyether-substituted alkyl, nitro-substituted alkyl, halo-substituted alkyl, aryl, alkoxy-substituted aryl, polyether-substituted aryl, nitro-substituted aryl, halo-substituted aryl, heteroaryl, alkoxy-substituted heteroaryl, polyether-substituted heteroaryl, nitro-substituted heteroaryl, halo-substituted heteroaryl, and the like. In certain embodiments the substituents are aryl, e.g., phenyl, alkoxy-substituted phenyl (particularly lower alkoxy-substituted phenyl such as methoxyphenyl), polyether-substituted phenyl (particularly phenyl substituted with a —CH₂ (OCH₂ CH₂)ₙOCH₃ or —(OCH₂CH₂)₂OCH₃ group where n is generally 1 to 12, preferably 1 to 6, most preferably 1 to 3), and halo-substituted phenyl (particularly fluorinated or chlorinated phenyl).

Another exemplary electroluminescent polymer material that is described in U.S. Pat. No. 6,414,104, is an arylamine-substituted poly(arylene-vinylene) polymer that contains monomer units having the general structure of formula (III) as follows:

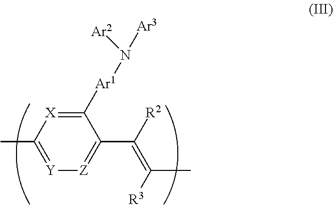

Wherein: X, Y and Z are independently selected from the group consisting of N, CH and CR⁶ wherein R⁶ is halo, cyano, alkyl, substituted alkyl, heteroatom-containing alkyl, aryl, heteroaryl, substituted aryl, or substituted heteroaryl, or wherein two R⁶ moieties on adjacent carbon atoms may be linked to form an additional cyclic group;

Ar¹ is as defined above;

Ar² and A³ are independently selected from the group consisting of aryl, heteroaryl, substituted aryl and substituted heteroaryl containing one or two aromatic rings; and

R² and R³ are as defined above.

In formula (I) above, the polymer is a poly(phenylene vinylene) derivative when X, Y and Z are all CH. When at least one of X, Y and Z is N, the aromatic ring will be, for example, substituted or unsubstituted pyridinyl, pyridazinyl, pyrimidinyl, pyrazinyl, 1,2,4-triazinyl, or 1,2,3-triazinyl. For instance, one of X, Y and Z may be CH and the other two may be either CH or CR⁶, wherein R⁶ may be a heteroatom-containing alkyl, for instance, alkoxy, or a polyether substituent —CH₂(OCH₂CH₂)ₙOCH₃ or —(OCH₂CH₂)ₙOCH₃ group where n is may be 1 to 12, for instance, 1 to 6, such as 1 to 3.

The polymer may be a homopolymer or a copolymer with at least one additional type of monomer unit. Preferably, if the polymer is a copolymer, the additional monomer units are also arylene-vinylene monomer units, for example having the structure of Formula (IV):

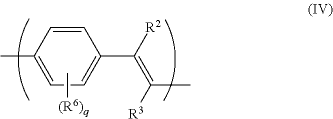

wherein R², R³ and R⁶ are as defined previously and q is an integer in the range of zero to 4 inclusive.

Examples of specific polymers having the structure of formula (1) are poly(2-(4-diphenylamino-phenyl)-1,4-phenylene vinylene and poly(2-(3-diphenylaminophenyl)-1,4-phenylene vinylene.

Examples of specific polymers disclosed in U.S. Pat. No. 6,414,104 are poly(2-(4-diphenylamino-phenyl)-1,4-phenylene vinylene and poly(2-(3-diphenylaminophenyl)-1,4-phenylene vinylene.

Electroluminescent polymers appropriate for use in this invention are also described in U.S. Pat. Nos. 6,723,828, 6,800,722, and 7,098,297, both of which are incorporated by reference herein. In those referenced patents there is disclosed a conjugated polymer containing monomer units having the structure of formula (V):

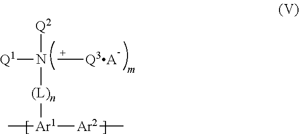

Wherein: Ar¹ and Ar² are independently selected from the group consisting of monocyclic, bicyclic and polycyclic arylene, heteroarylene, substituted arylene and substituted heteroarylene groups;

L is alkylene, alkenylene, substituted alkylene, substituted alkenylene, heteroalkylene, heteroalkenylene, substituted heteroalkylene, substituted heteroalkenylene, arylene, heteroarylene, substituted arylene or substituted heteroarylene;

m is zero or 1;

n is zero or 1;

Q¹ and Q² are independently selected from the group consisting of H, aryl, heteroaryl, substituted aryl, substituted heteroaryl, alkyl, and substituted alkyl, and Q³ is selected from the group consisting of alkyl and substituted alkyl, with the proviso that when m is 1, Q¹ and Q² are other than H; and

A⁻ is a negatively charged counterion.

The electroluminescent material may also include blends of polymers within formula (IV) with other polymers, as well as a variety of copolymers.

The sealant may comprise any material capable of forming a bond between the materials used in the encapsulation. For example, wherein the encapsulation layer and substrate are both glass, the sealant may be any material capable of bonding glass to glass. The sealant may be a curable synthetic or natural resin (e.g., an epoxy or other material that requires a chemical reaction for curing) or an adhesive that cures by solvent evaporation. In some embodiments, the sealant is a UV-curable epoxy.

The invention disclosed herein is suitable for preparing, for example, electroluminescent devices such as OLEDs. Additionally, other optoelectronic (e.g., photovoltaic and electrochromic) devices with energy management capabilities can benefit from the use of encapsulation as disclosed herein. The devices employing encapsulation as described herein benefit from a variety of advantages over traditional devices. For example, in some embodiments the positioning of the desiccant in the encapsulation of the invention provides more effective protection for the encapsulated device against harmful environmental factors such as water vapor. Furthermore, in some embodiments the positioning of the desiccant allows the devices to be either top-emitting or bottom-emitting.

The devices and encapsulation described herein are manufactured using standard techniques and methods. For example, as described herein, the grooves may be prepared using any suitable technique, such as photolithography and other etching techniques.

Examples of encapsulation configurations are provided in the attached Figures and are described in more detail in the following paragraphs.

Encapsulation Configuration A comprises an encapsulation layer having a rim and a substrate that does not have a rim. In embodiments, the rim of the encapsulation layer comprises a groove, or the substrate comprises a groove, or both the substrate and the rim of the encapsulation layer comprise grooves.

Encapsulation Configuration B comprises a substrate having a rim and an encapsulation layer that doe not have a rim. In embodiments, the rim of the substrate comprises a groove, or the encapsulation layer comprises a groove, or both the rim of the substrate and the encapsulation layer comprise grooves.

Encapsulation Configuration C comprises a substrate having a rim and an encapsulation layer that also has a rim. In embodiments, the rim of the substrate comprises a groove, or the rim of the encapsulation layer comprises a groove, or both the rim of the substrate and the rim of the encapsulation layer comprise grooves.

Encapsulation Configuration D comprises a substrate and an encapsulation layer, neither of which have a rim. A spacer is present that is positioned around the periphery of the substrate and encapsulation layer. In embodiments, the spacer comprises a top groove and a bottom groove, or the encapsulation layer and substrate comprise grooves, or both the spacer and the encapsulation layer and/or substrate comprise grooves.

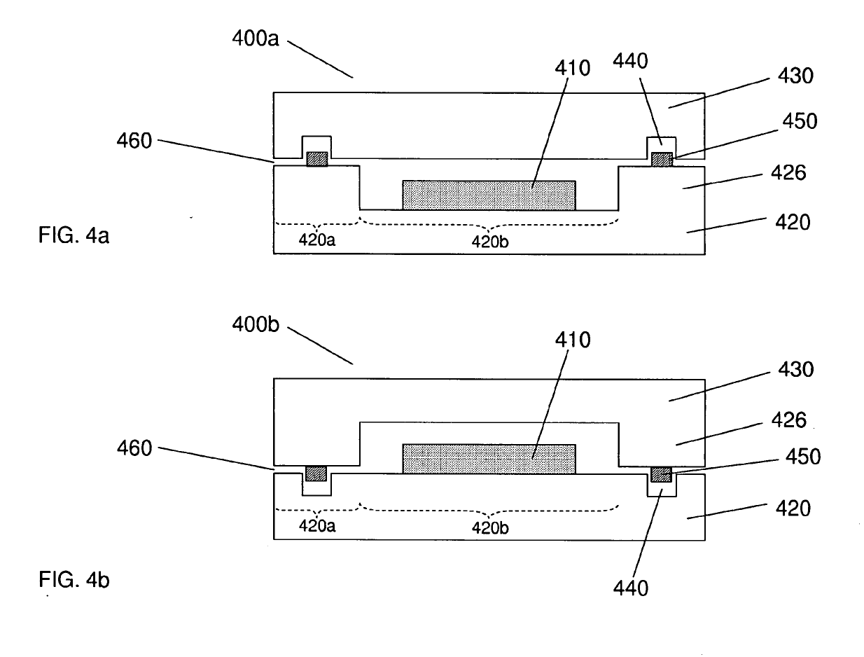

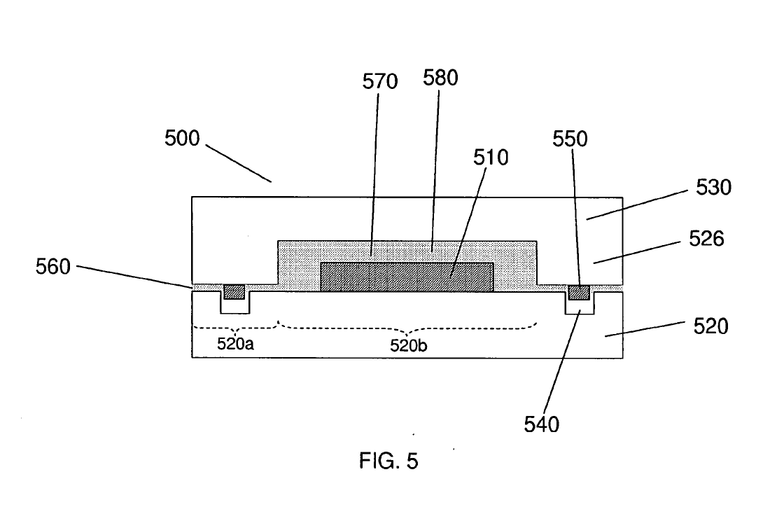

In configurations where either or both of the substrate and encapsulation does not have a rim (such as, but not limited to configurations A, B, and D), desiccant may be placed in the bonding area such that the desiccant is not in a groove. See, for example, FIGS. 4a and 4b and the description thereof below. Furthermore, in any of the configurations described herein, the sealing material used to bond the substrate to the encapsulation layer may be disposed only in the region between the encapsulation layer bonding region and the substrate bonding region, or the sealing material may completely or partially fill the device cavity as well. See, for example, FIG. 5 and the description thereof below.

The following paragraphs provide an explanation of some aspects of the figures. It will be appreciated that some items in the figures appear two or more times (e.g., because of symmetry of the depicted device), but only one such appearance is labeled for simplicity/clarity of the figures. It will be appreciated that the figures are not intended to be drawn to scale.

With reference to FIG. 1a, a top view of device 100a is shown. No encapsulation layer is shown in FIG. 1a, so device 100a is only a partially encapsulated device that is shown for illustrative purposes. Device stack 110 is disposed on substrate 120. Device stack 110 is smaller in area than substrate 120, such that substrate 120 extends beyond device stack 110. Substrate 120 comprises two regions: a device region and a bonding region. The boundary between the two regions of the substrate may be anywhere between edges 111 of device stack 110 and just inside edges 121 of substrate 120 (by “just inside” is meant that enough space remains for the substrate to bond to the encapsulation layer). Dashed line 122 represents one embodiment for the boundary between device region 120b and bonding region 120a. In such an embodiment, device region 120b is larger in area than device stack 110. In another embodiment, the boundary corresponds with edges 111 of device stack 110. In such an embodiment, the bonding region is represented by the combination of 120a and 120b, and the device region is the portion of substrate 120 that is directly below device stack 110.

With reference to FIG. 1b, a top view of device 100b is shown. Again, no encapsulation layer is shown in FIG. 1b, so device 100b is only a partially encapsulated device that is shown for illustrative purposes. Device stack 110 is disposed on substrate 120. Substrate 120 comprises two regions: a device region (not labeled) and bonding region 126. In device 100b, the device region and device stack 110 are the same size, such that device stack 110 completely covers the device region and extends up to bonding region 126. In other embodiments (not shown), the device stack is smaller than the device region. Groove 140 is disposed within bonding region 126. In one embodiment of FIG. 1b, bonding region 126 is coplanar with the device region. In another embodiment of FIG. 1b, bonding region 126 comprises a rim and is elevated from (i.e., not coplanar with) the device region:

In FIG. 1c and FIG. 1d, devices 100c and 100d are shown, respectively. Device 100c is similar to device 100b but comprises two concentric grooves 140. Device 100d is similar to 100c but comprises discontinuous, staggered grooves 140.

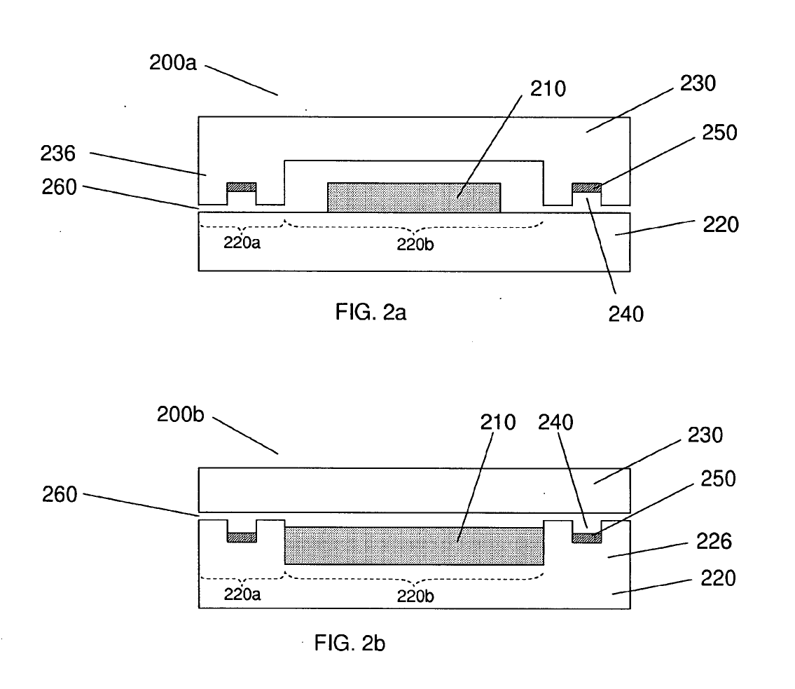

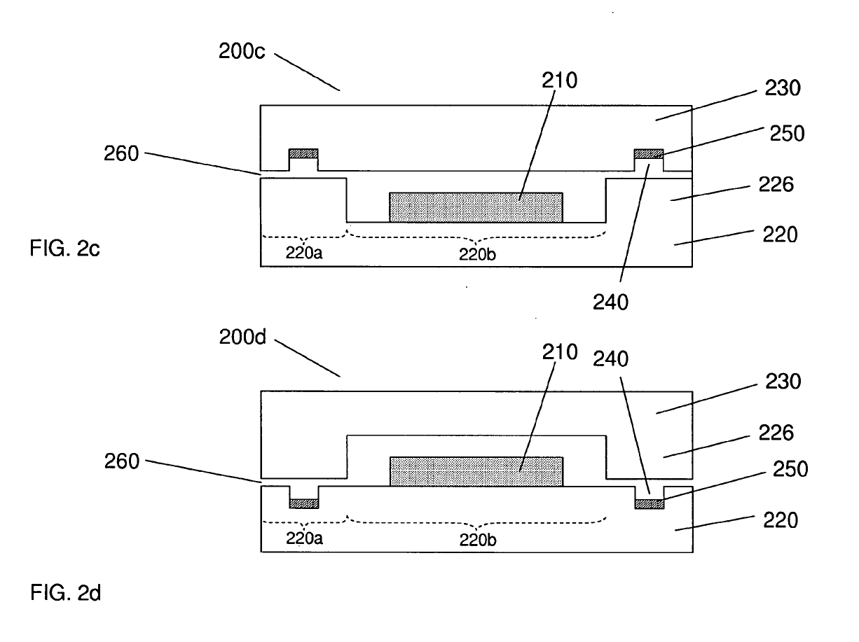

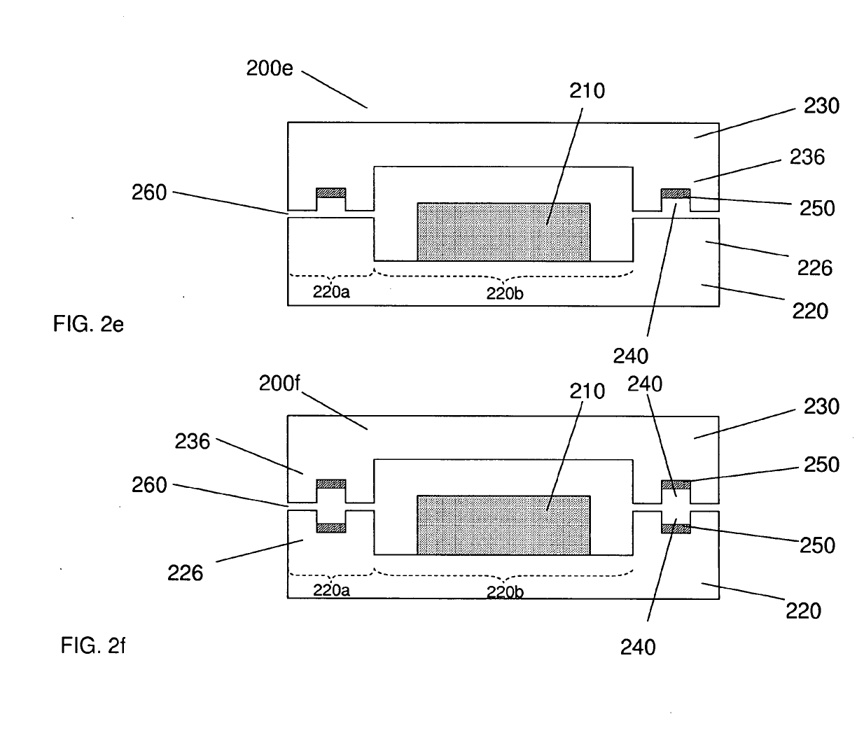

With reference to FIG. 2a, a cross section of device 200a is shown. Device 200a is an illustration of Encapsulation Configuration A. Thus, substrate 220 is flat and smooth, and comprises device region 220b and bonding region 220a (only one bonding region is labeled for simplicity). Device stack 210 is disposed on substrate 220 in device region 220b, and is smaller than device region 220b. Encapsulation layer 230 fits over, but does not contact, device stack 210. Around the periphery of encapsulation layer 230 is rim 236. Etched into rim 236 is groove 240. Disposed within groove 240 is desiccant 250. Between encapsulation layer 230 and bonding region 220a is transition region 260, which comprises a sealant (not shown) that bonds encapsulation layer 230 and substrate 220.

With reference to FIG. 2b, a cross section of device 200b is shown. Device 200b is an illustration of Encapsulation Configuration B. Thus, encapsulation layer 230 does not have a rim. Around the periphery of substrate 220 is rim 226, and rim 226 comprises groove 240. Device stack 210 is disposed on substrate 220 and is shown in the figure as being equal in size to device region 220b. Furthermore, rim 226 is equal in size to bonding region 220a.

With reference to FIG. 2c, a cross section of device 200c is shown. Device 200c is an illustration of Encapsulation Configuration B. Thus, encapsulation layer 230 does not contain a rim, although encapsulation layer 230 comprises groove 240. Around the periphery of substrate 220 is rim 226.

With reference to FIG. 2d, a cross section of device 200d is shown. Device 200d is an illustration of Encapsulation Configuration A. Thus, substrate 220 does not contain a rim, although substrate 220 comprises groove 240. Around the periphery of encapsulation layer 230 is rim 226.

With reference to FIG. 2e, a cross section of device 200e is shown. Device 200e is an illustration of Device Configuration C. Thus, substrate 220 comprises rim 226 and encapsulation layer 230 comprises rim 236. Groove 240 and desiccant 250 are present in encapsulation layer 230 but not in substrate 220. In an alternative embodiment (not shown), groove 240 and desiccant 250 are present in substrate 220 but not in encapsulation layer 230.

With reference to FIG. 2f, a cross section of device 200f is shown. Device 200f is an illustration of Encapsulation Configuration C. Thus, substrate 220 comprises rim 226 and encapsulation layer 230 comprises rim 236. Groove 240 and desiccant 250 are present in encapsulation layer 230 and in substrate 220.

With reference to FIG. 3a, a cross section of device 300a is shown. Device 300a is an illustration of Encapsulation Configuration D. Thus, substrate 320 and encapsulation layer 330 have no rims. Spacer 370 is present and comprises groove 340 and desiccant 350. Spacer 370 surrounds device stack 310 and is thus located at the periphery of substrate 320 and encapsulation layer 330.

With reference to FIG. 3b, a cross section of device 300b is shown. Device 300b is an illustration of Encapsulation Configuration D. Thus, substrate 320 and encapsulation layer 330 have no rims but comprise groove 340 and desiccant 350. Spacer 370 is present and is shown in FIG. 3b as having flat surfaces that interface with substrate 320 and encapsulation layer 330. Spacer 370 surrounds device stack 310 and is thus located at the periphery of substrate 320 and encapsulation layer 330.

With reference to FIG. 4a, a cross section of device 400a′is shown. Device 400a is an illustration of Encapsulation Configuration B. Thus, encapsulation layer 430 does not contain a rim, although encapsulation layer 430 comprises groove 440. Around the periphery of substrate 420 is rim 426. The desiccant is disposed on bonding area 420a of substrate 420, not (initially) in groove 440. When substrate 420 and encapsulation layer 430 are brought together and sealed, it will be appreciated that desiccant 450 as shown in FIG. 4a will extend into groove 440.

With reference to FIG. 4b, a cross section of device 400b is shown. Device 400b is an illustration of Encapsulation Configuration A. Thus, encapsulation layer 430 contains rim 426. Substrate 420 comprises groove 440. The desiccant is disposed on the bonding area (not labeled) of encapsulation layer 430, not (initially) in groove 440. When substrate 420 and encapsulation layer 430 are brought together and sealed, it will be appreciated that desiccant 450 as shown in FIG. 4a will extend into groove 440.

With reference to FIG. 5, a cross section of device 500 is shown. Encapsulation layer 530 and substrate 520 form device cavity 570 and transition region 560. Bonding material 580 completely fills device cavity 570 and transition region 560. Optionally, additional bonding material (not shown) may fill grooves 540.

It will be appreciated that the encapsulated devices shown in the figures are merely representative and are not meant to be limiting.

All patents, patent applications, and publications mentioned herein are hereby incorporated by reference in their entireties. However, where a patent, patent application, or publication containing express definitions is incorporated by reference, those express definitions should be understood to apply to the incorporated patent, patent application, or publication in which they are found, and not to the remainder of the text of this application, in particular the claims of this application.

It is to be understood that while the invention has been described in conjunction with the preferred specific embodiments thereof, that the foregoing description as well as the examples that follow, are intended to illustrate and not limit the scope of the invention. It will be understood by those skilled in the art that various changes may be made and equivalents may be substituted without departing from the scope of the invention, and further that other aspects, advantages and modifications will be apparent to those skilled in the art to which the invention pertains.

### EXAMPLES

### Example 1

An example process for producing the cover glass (second substrate) is as described in the following paragraphs.

1) A desiccant chamber is created. A groove is created on the edge of the cover glass outside (and surrounding) the device chamber area (see, for example, FIG. 1b). This is achieved by using a standard photolithography and an etching process (either wet chemical etch or dry etch). Alternatively, the groove can also be embossed at elevated temperature. This can be done at the same time when creating the device chamber or done separately.

2) A proper amount of liquid desiccant (typically, although not necessarily, a commercially available material) is dispensed into the groove and cured. Alternatively, a solid state desiccant (such as calcium metal) can be deposited into the groove using physical vapor deposition process via a shadow mask.

3) Sealant (such as an UV epoxy) is applied to the sealing surfaces of the cover glass. The cover is attached to the OLED device.

What is claimed is:

1. An encapsulation for an electronic device comprising an encapsulation layer and a substrate, wherein:
the substrate comprises a surface comprising a device region and a bonding region surrounding the device region, wherein the bonding region optionally comprises a groove for receiving a liquid or solid desiccant; and
the encapsulation layer comprises a bonding region suitable for contacting a substrate and optionally further comprises a groove suitable for receiving a liquid or solid desiccant, provided that at least one of the encapsulation layer and the substrate comprises a groove.

2. The encapsulation of claim 1, wherein the bonding region of the substrate is located around the periphery of the substrate and is disposed on an elevated rim.

3. The encapsulation of claim 1, wherein the bonding region of the encapsulation layer is located around the periphery of the encapsulation layer and is disposed on an elevated rim.

4. The encapsulation of claim 2, wherein the groove is present in the substrate bonding region and is disposed on a surface of the elevated rim.

5. The encapsulation of claim 3, wherein the groove is present in the encapsulation layer bonding region and is disposed on a surface of the elevated rim.

6. An electronic device comprising:
a plurality of device layers arranged in a component stack, wherein the component stack comprises a top face, a bottom face, and peripheral edges; and
an encapsulation surrounding the component stack and comprising a first substrate, a second substrate, a sealant, a desiccant, and an optional spacer,
wherein the sealant forms a bond between the first and second substrates, and
wherein the desiccant is positioned within the encapsulation around the peripheral edges of the component stack.

7. The electronic device of claim 6, wherein:
the first substrate comprises a device region, a first bonding region surrounding the device region, and an optional first groove disposed in the first bonding region;
the second substrate comprising a second bonding region and an optional second groove disposed in the second bonding region; and
when the optional spacer is present it optionally comprises a groove and is configured to make contact with the first substrate in the first bonding region and with the second substrate in the second bonding region,
provided that at least one groove is present in either the first substrate, the second substrate, or the optional spacer.

8. The electronic device of claim 7, wherein the desiccant is disposed within the at least one groove.

9. The electronic device of claim 6, wherein one or both of the first and second substrates comprise a rim.

10. The electronic device of claim 9, wherein the first substrate comprises a rim, and the first bonding region is partially or completely disposed on a surface of the rim, or wherein the second substrate comprises a rim, and the second bonding region is partially or completely disposed on a surface of the rim.

11. The electronic device of claim 9, wherein the first substrate comprises a rim and the second substrate comprises a rim, and wherein the first bonding region is partially or completely disposed on the rim of the first substrate and the second bonding region is partially or completely disposed on the rim of the second substrate.

12. The electronic device of claim 7, wherein the first and second grooves are present and the optional spacer is not present, and wherein the first and second grooves are positioned such that their centers are substantially aligned.

13. The electronic device of claim 7, wherein the desiccant partially or completely fills the first groove, the second groove, the groove in the spacer, or any combination thereof.

14. The electronic device of claim 6, wherein the electronic component stack comprises a bottom electrode contacting the first substrate, an electroluminescent layer, and a top electrode, and wherein the electronic device is configured to emit photons through the first substrate, through the second substrate, or through both the first and second substrates.

15. A method for encapsulating an electronic device, the method comprising:
providing a first substrate, a second substrate, and an optional spacer;
forming a groove in the first substrate, the second substrate, the optional spacer, or any combination thereof;
depositing a desiccant in the groove; and
bonding the first substrate to the second substrate using a sealant.

16. The method of claim 15, wherein the groove is formed around the periphery of the first substrate, the periphery of the second substrate, or the periphery of both the first and second substrates.

17. The method of claim 15, wherein the first substrate is provided having the component layers of an electronic device disposed thereon.

18. The method of claim 15, wherein the method comprises forming a groove in the first substrate, and wherein the component layers of an electronic device are deposited on the first substrate after the groove is formed in the first substrate.

19. The method of claim 15, wherein the method comprises forming a groove in the second substrate but not the first substrate.

20. The method of claim 15, wherein the first substrate has an elevated rim, or wherein the second substrate has an elevated rim, or wherein the first substrate and the second substrate both have elevated rims.
